(19) United States
(12) Patent Application Publication
(10) Pub. No.: US 2013/0049107 A1
(43) Pub. Date: Feb. 28, 2013

(54) TRENCH SEMICONDUCTOR POWER DEVICE AND FABRICATION METHOD THEREOF

(71) Applicant: Koon Chong So, Shatin Hong Kong (CN)

(72) Inventor: Koon Chong So, Shatin Hong Kong (CN)

(73) Assignee: M-MOS SEMICONDUCTOR HK LTD, Shatin Hong Kong (CN)

(21) Appl. No.: 13/576,702

(22) PCT Filed: Jun. 29, 2010
(86) PCT No.: PCT/CN2010/074664

§ 371 Date: Oct. 10, 2012

(30) Foreign Application Priority Data
Feb. 3, 2010 (CN) 201010104901.7

(51) Int. Cl. H01L 21/336; H01L 29/78

(52) U.S. Cl. 257/331; 438/270; 257/E29.262; 257/E21.41

(57) ABSTRACT

A trench semiconductor power device and a fabrication method. The fabrication method includes: eroding an n epitaxial layer on an n+ substrate to form multiple gate trenches, and implanting with dopants to form source regions and P type base regions, respectively; eroding an interlayer dielectric to form a trench plug; and eroding an aluminum copper alloy to form a metal pad layer and wires. The method forms the source regions and the base regions by directly implanting, does not need source region masks and base region masks, has a simple fabrication process, and improves the quality and reliability of the device.

### PRIORITY CLAIM

The present application is a National Phase entry of PCT Application No. PCT/CN2010/074664, filed Jun. 29, 2010, which which claims priority from Chinese Application 201010104901.7, filed Feb. 3, 2010, the disclosures of which are hereby incorporated by reference herein in their entirety.

### FIELD OF THE INVENTION

The present invention relates to a semiconductor power device, in particular to a trench semiconductor power device and a manufacturing method thereof.

### BACKGROUND OF THE INVENTION

With the development of semiconductor power devices, many electronic devices have become smaller and smaller but their efficiency has becomes higher. As a main part in power semiconductor devices, power MOSFETs are widely applied in portable communication terminals, notebook computers, automobiles and consumer electronics fields, and are an important part in discrete devices and smart power integrated circuits (SPICs). A power MOSFET has advantages in the above fields mainly due to the following characteristics: it is a device controlled by voltage, has high input impedance, low driving power, and can be easily coupled to the preceding stage; the drain current has a negative temperature coefficient, there is no secondary breakdown, the safety operation area (SOA) is wide, and the thermostability is high; it is a majority-carrier device, with high irradiation resistance; it has no minority-carrier memory effect, and has high switching speed; multiple units work in parallel to each other, and therefore high output power can be obtained. An ideal power MOSFET can withstand high blocking voltage in an OFF state, has a low forward voltage drop in an ON state, and has high current treatment capability and high switching speed, and thereby the switching loss is reduced.

To improve the performance of a power MOSFET, more attention should be paid to optimize the process conditions and improve the device structure. The structure of a trench terminal region of a low-voltage N-channel trench power MOSFET and the implementation method thereof are introduced in a Japanese journal—Applied Physics (vol. 3, 2008). The structure of the trench power MOSFET is shown in FIG. 29, wherein, the active region is on the left, the drain terminal is on the bottom of the structure, and the scribe line is at the right end. There are three trenches between the terminal of active region and the scribe line, the P-type base region is defined as the source electrode or drain electrode of PMOS, the trench bottom is the channel of PMOS, the N-drift region is the base region of PMOS, the polysilicon filled in the trench serves as the gate electrode of PMOS, and is electrically connected to the P-type base region on the left.

FIG. 30 of US20080227269A1 shows the structure of another trench power MOSFET and the implementation method thereof, wherein, the trench power MOSFET comprises active region 10, terminal region 12, gate electrode trench 14, base region 16, drift region 18, thin oxide layer 20, thick oxide layer 22, source region 26, contact hole region 28, epitaxial layer 31, substrate 32, thicker oxide layer 40, and source electrode (contact) metal, etc.; during the manufacturing process, the base region is formed on the epitaxial layer before the trenches are masked, the base region mask is omitted, the source region mask is utilized for injection of doping agent to form source region.

In the manufacturing process of the trench power MOSFET with above-mentioned structure (FIGS. 29 and 30), though the P-type base region is formed without a base region mask, an N+ source region mask is required to form the source region of NMOS; the manufacturing procedures are complex, and the quality and reliability of the obtained device are poor.

### SUMMARY OF THE INVENTION

To overcome the drawbacks in the prior art, the present invention provides a trench semiconductor power device and a manufacturing method thereof; the method can simplify the manufacturing procedures of a trench semiconductor power device, avoid pollution caused by relevant procedures, improve the quality and reliability of the device, and reduce cost and manufacturing time.

To achieve the above-mentioned object, the manufacturing method of trench semiconductor power device provided in the present invention comprises the following steps:
first, etching the epitaxial layer on the substrate through a trench mask to form a plurality of gate electrode trenches, and injecting doping agents to form a source region and a base region, respectively;
then, etching the interlayer dielectric through a contact hole mask to form contact trenches, and filling the contact trenches to form trench plugs;
finally, etching the metal through a metal mask to form a metal pad layer and wires.

In an embodiment, the manufacturing method further comprises the following steps:
1) Dry-etching the exposed oxide layer through the trench mask;
2) Injecting an N-type doping agent, and diffusing the N-type doping agent into the epitaxial layer by annealing treatment to form a source region;
3) Forming trenches in the epitaxial layer, and removing the oxide layer;
4) Treating the trenches by sacrificing treatment, and filling the trenches;
5) Injecting a P-type doping agent to form a base region, and diffusing the base region into the epitaxial layer by annealing treatment;
6) Forming an interlayer dielectric on the top layer, and forming contact trenches through a contact hole mask;
7) Filling the contact trenches to form trench plugs;
8) Depositing a layer of Al—Cu alloy on the interlayer dielectric, and etching the metal through a metal mask to form a metal pad layer and wires.

In some embodiments, the manufacturing method further comprises the following steps:
1) Dry-etching the exposed oxide layer through the trench mask;
2) Forming trenches in the epitaxial layer, and removing the oxide layer;
3) Treating the trenches by sacrificing treatment, and filling the trenches;
4) Injecting a P-type doping agent to form a base region, and diffusing the P-type base region into the epitaxial layer by annealing treatment;
5) Injecting an N-type doping agent into the P-type base region to form a source region, and diffusing the N-type source region into the P-type base region by annealing treatment;
6) Forming an interlayer dielectric on the top layer, and forming contact trenches through a contact hole mask;
7) Filling the contact trenches to form trench plugs;
8) Depositing a layer of Al—Cu alloy on the interlayer dielectric, and etching the metal through a metal mask to form a metal pad layer and wires.

Furthermore, the injection of N-type doping agent is accomplished by directly injecting an N-type doping agent through the oxide layer into the epitaxial layer or directly injecting an N-type doping agent through the gate oxide layer into the P-type base region; the injection of the P-type doping agent is accomplished by directly injecting the P-type doping agent through the gate oxide layer into the epitaxial layer. In these steps, the procedures of forming an oxide layer, exposing and etching the oxide layer through a source region/base region mask before injection of a doping agent are omitted.

To achieve the above-mentioned object, the present invention provides a trench semiconductor power device, wherein, the trench semiconductor power device is manufactured with the manufacturing method described above.

The present invention has obvious advantages and beneficial effects: with the manufacturing method provided in the present invention, the procedure of utilization of a source region mask and a base region mask can be omitted, and a source region and a base region can be formed through direct injection; therefore, the device with a new structure can be manufactured through less manufacturing steps, and the quality and reliability of the device can be greatly improved; in addition, since the procedures of forming and etching an oxide layer are omitted in the manufacturing method provided in the present invention, environmental pollution can be reduced.

### BRIEF DESCRIPTION OF THE DRAWINGS

The accompanying drawings are provided to help the person skilled in the art further understand the present invention, and constitute a part of the description. These drawings are used in conjunction with the embodiments to interpret the present invention, but don't constitute any limitation to the present invention. Among the drawings:

FIG. 1 is a schematic diagram of oxide layer exposure in the manufacturing method of a trench semiconductor power device of the present invention;

FIG. 2 is a schematic diagram of epitaxial layer exposure in the manufacturing method of a trench semiconductor power device of the present invention;

FIG. 3 is a schematic diagram of example 1 of the manufacturing method of a trench semiconductor power device of the present invention, wherein, an N-type doping agent is injected without utilizing a source region mask;

FIG. 4 is a schematic diagram of formation of an N-type source region in embodiment 1 of the manufacturing method of a trench semiconductor power device of the present invention;

FIG. 5 is a schematic diagram of formation of gate electrode trenches in embodiment 1 of the manufacturing method of a trench semiconductor power device of the present invention;

FIG. 6 is a schematic diagram of oxide layer removal in embodiment 1 of the manufacturing method of a trench semiconductor power device of the present invention;

FIG. 7 is a schematic diagram of formation of gate oxide layer in embodiment 1 of the manufacturing method of a trench semiconductor power device of the present invention;

FIG. 8 is a schematic diagram of formation of polysilicon gate in embodiment 1 of the manufacturing method of a trench semiconductor power device of the present invention;

FIG. 9 is a schematic diagram of example 1 of the manufacturing method of a trench semiconductor power device of the present invention, wherein a P-type doping agent is injected without utilizing a base region mask;

FIG. 10 is a schematic diagram of formation of a P-type base region in embodiment 1 of the manufacturing method of a trench semiconductor power device of the present invention;

FIG. 11 is a schematic diagram of formation of an interlayer dielectric in embodiment 1 of the manufacturing method of a trench semiconductor power device of the present invention;

FIG. 12 is a schematic diagram of formation of contact trenches in embodiment 1 of the manufacturing method of a trench semiconductor power device of the present invention;

FIG. 13 is a schematic diagram of formation of trench plugs in embodiment 1 of the manufacturing method of a trench semiconductor power device of the present invention;

FIG. 14 is a schematic diagram of formation of metal pad layer and wires in embodiment 1 of the manufacturing method of trench semiconductor power device of the present invention;

FIG. 15 is a schematic diagram of formation of gate electrode trenches in embodiment 2 of the manufacturing method of a trench semiconductor power device of the present invention;

FIG. 16 is a schematic diagram of oxide layer removal in embodiment 2 of the manufacturing method of a trench semiconductor power device of the present invention;

FIG. 17 is a schematic diagram of formation of a gate oxide layer in embodiment 2 of the manufacturing method of a trench semiconductor power device example the present invention;

FIG. 18 is a schematic diagram of formation of a polysilicon gate in embodiment 2 of the manufacturing method of a trench semiconductor power device of the present invention;

FIG. 19 is a schematic diagram of embodiment 2 of the manufacturing method of a trench semiconductor power device of the present invention, wherein a P-type doping agent is injected without utilizing a base region mask;

FIG. 20 is a schematic diagram of formation of P-type base region in embodiment 2 of the manufacturing method of a trench semiconductor power device of the present invention;

FIG. 21 is a schematic diagram of embodiment 2 of the manufacturing method of trench semiconductor power device of the present invention, wherein an N-type doping agent is injected without utilizing a source region mask;

FIG. 22 is a schematic diagram of formation of an N-type source region in embodiment 2 of the manufacturing method of a trench semiconductor power device of the present invention;

FIG. 23 is a schematic diagram of formation of an interlayer dielectric in embodiment 2 of the manufacturing method of a trench semiconductor power device of the present invention;

FIG. 24 is a schematic diagram of formation of contact trenches in embodiment 2 of the manufacturing method of a trench semiconductor power device of the present invention;

FIG. 25 is a schematic diagram of formation of trench plugs in embodiment 2 of the manufacturing method of a trench semiconductor power device of the present invention;

FIG. 26 is a schematic diagram of formation of a metal pad layer and wires in embodiment 2 of the manufacturing method of a trench semiconductor power device of the present invention;

FIG. 27 is a schematic diagram of formation of contact trenches in embodiment 3 of the manufacturing method of a trench semiconductor power device of the present invention;

FIG. 28 is a schematic diagram of formation of contact trenches in embodiment 4 of the manufacturing method of a trench semiconductor power device of the present invention;

FIG. 29 is a schematic structural diagram of a prior art trench semiconductor power device disclosed in Japan;

FIG. 30 is a schematic structural diagram of a prior art trench semiconductor power device disclosed in USA;

### DETAILED DESCRIPTION

Hereunder embodiments of the present invention will be described with reference to the accompanying drawings. It should be understood that the embodiments described here are only used to describe and interpret the present invention, but don't constitute any limitation to the present invention.

In a manufacturing method of trench semiconductor power device of the present invention, firstly, a plurality of gate electrode trenches are formed by etching an epitaxial layer on the substrate through a trench mask, and a source region and a base region are respectively formed through injection of a doping agent; then, the interlayer dielectric is etched through a contact hole mask to form contact trenches, and the contact trenches are filled with titanium or titanium nitride and tungsten layers to form trench plugs; finally, the metal is etched through metal mask to form metal pad layer and wires.

### Embodiment 1

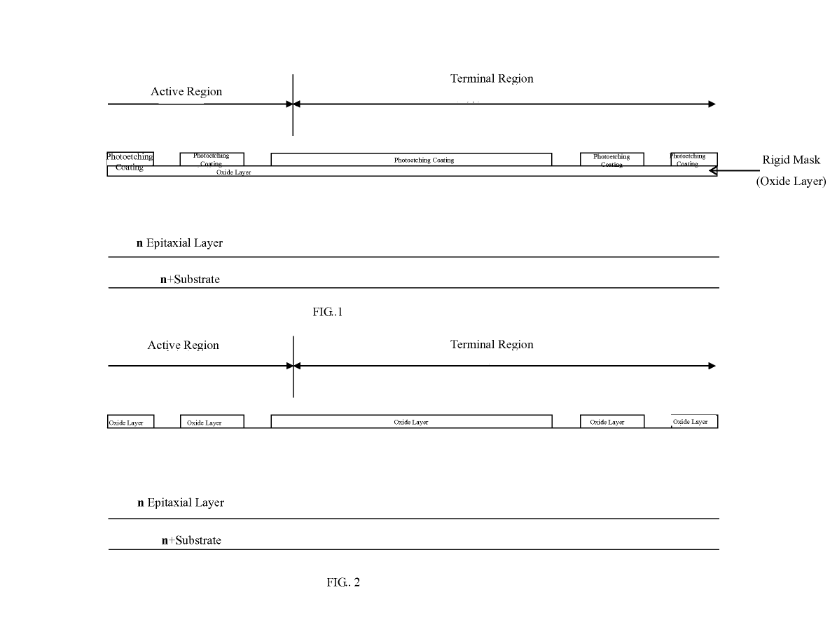

As shown in FIG. 1, an epitaxial layer is placed on the substrate; first, an oxide layer (a rigid oxide photomask) is formed by deposition or thermal growth on the epitaxial layer, and a photoetching coating is formed by deposition on the oxide layer; then, some parts of the oxide layer are exposed through the pattern formed by a trench mask.

As shown in FIG. 2, the oxide layer exposed through the pattern formed by the trench mask is dry-etched and thereby the epitaxial layer is exposed, and then the photoetching coating is removed.

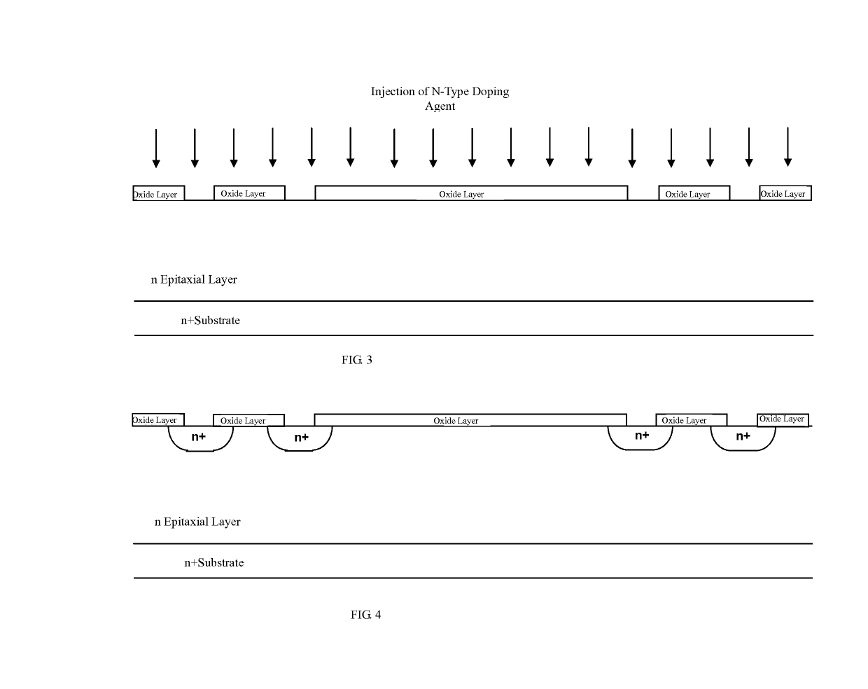

As shown in FIG. 3, the procedures of formation of an oxide layer, exposure of the oxide layer through a source region mask, and etching of the oxide layer are omitted; instead, an N-type doping agent is injected directly through the oxide layer into the epitaxial layer, excluding the parts covered by the oxide layer; the N-type doping agent is phosphorus or arsenic.

As shown in FIG. 4, in the treatment process, the injected N-type doping agent is diffused into the epitaxial layer by annealing treatment, so as to form an N-type source region. The depth of the N-type source region depends on several factors, including the type of doping agent, injection energy, concentration, annealing time, etc. The required concentration and depth can be achieved by adjusting these factors.

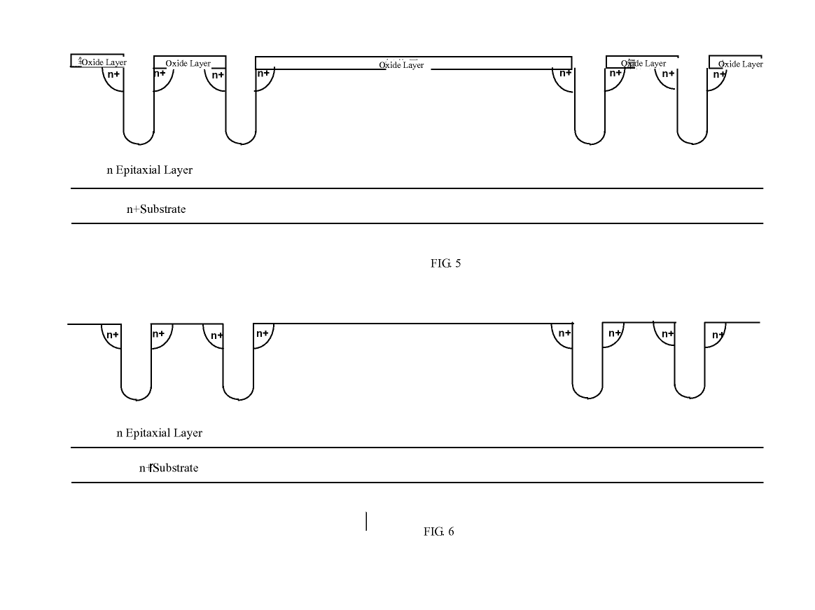

As shown in FIG. 5, trenches are formed by etching in the N-type source region, and the trenches extend through the N-type source region to the epitaxial layer.

As shown in FIG. 6, after the trenches are formed, the oxide layer is removed to expose the N-type source region and epitaxial layer.

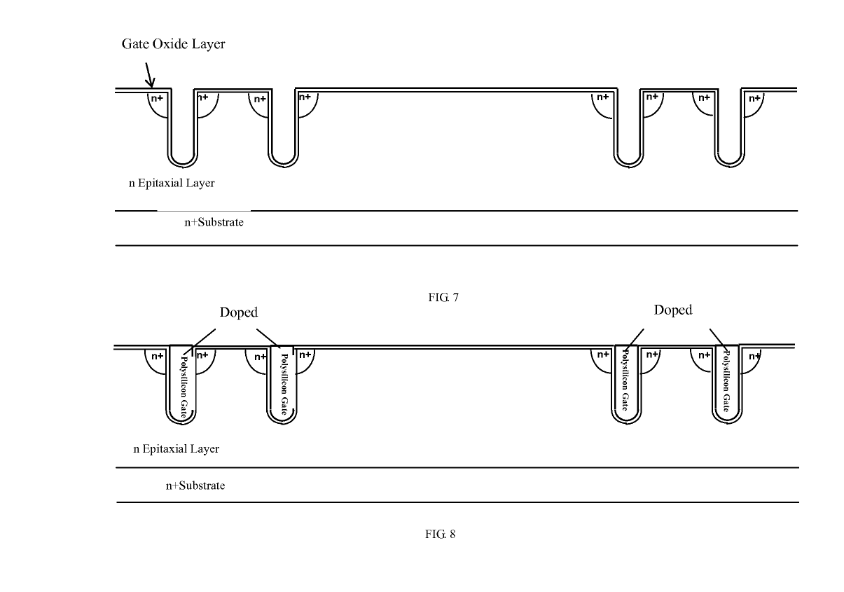

As shown in FIG. 7, the trenches are treated by sacrificing oxidation, to eliminate the silicon layer damaged by plasma during the trenching process; in addition, a thin gate oxide layer is formed on the exposed side walls and bottom of the trenches and the upper surface of N-type source region and epitaxial layer by thermal growth.

As shown in FIG. 8, a layer of doped polysilicon (polysilicon that contains doping agent) is deposited in the trenches, to fill the trenches and cover the top surfaces; then, the polysilicon layer is chemically and mechanically polished.

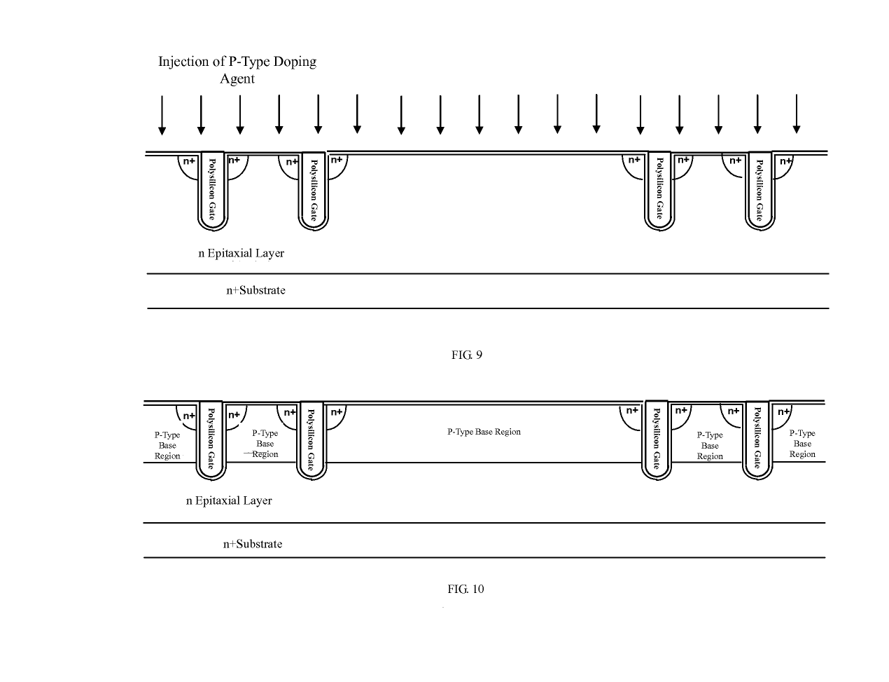

As shown in FIG. 9, the procedures of formation of an oxide layer, exposure of the oxide layer through a base region mask, and etching of the oxide layer are omitted; instead, a P-type doping agent is injected directly through the gate oxide layer into the epitaxial layer, to form a P-type base region on the epitaxial layer.

As shown in FIG. 10, the P-type base region is diffused into the epitaxial layer by annealing treatment. The depth of the P-type base region depends on several factors, including the type of doping agent, injection energy, concentration, annealing time, etc. The required concentration and depth can be achieved by adjusting these factors.

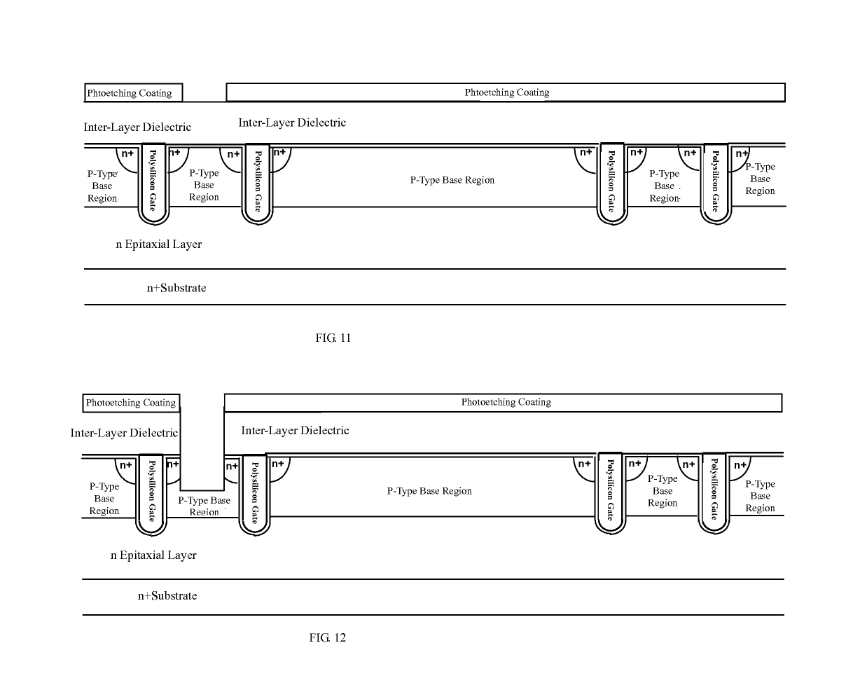

As shown in FIG. 11, to form contact hole trenches in the P-type base region and N-type source region, B-P glass and silicon dioxide are deposited on the top layer to form an interlayer dielectric.

As shown in FIG. 12, the interlayer dielectric is etched through a contact hole mask to form contact trenches; then, the epitaxial layer that contains the doping agent is etched, so that the contact trenches penetrate more deeply through the source region into the P-type base region.

As shown in FIG. 13, the contact trenches are dry-etched, and a titanium/titanium nitride layer is deposited on the side walls and bottom of the trenches and the upper surface of the epitaxial layer; then, the contact trenches are filled with tungsten to form trench plugs, and the top layer of the interlayer dielectric is etched to remove titanium/titanium nitride and tungsten.

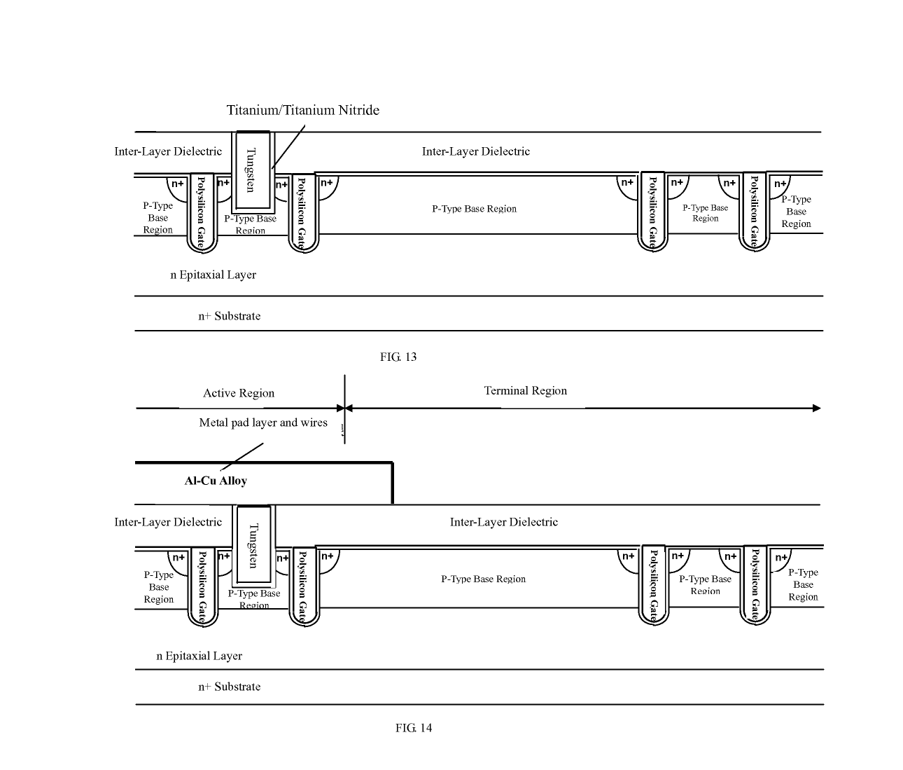

As shown in FIG. 14, a layer of Al—Cu alloy is deposited on the upper surface of the device, and then the metal is etched through metal mask to form metal pad layer and wires.

### Embodiment 2

First, an epitaxial layer is placed on the substrate, an oxide layer (a rigid oxide photomask) is formed by deposition or thermal growth on the epitaxial layer, and a photoetching coating is formed by deposition on the oxide layer; then, some parts of the oxide layer are exposed through the pattern formed by a trench mask; the parts of the oxide layer exposed through the pattern formed by trench mask are dry-etched to expose the epitaxial layer, and then the photoetching coating is removed.

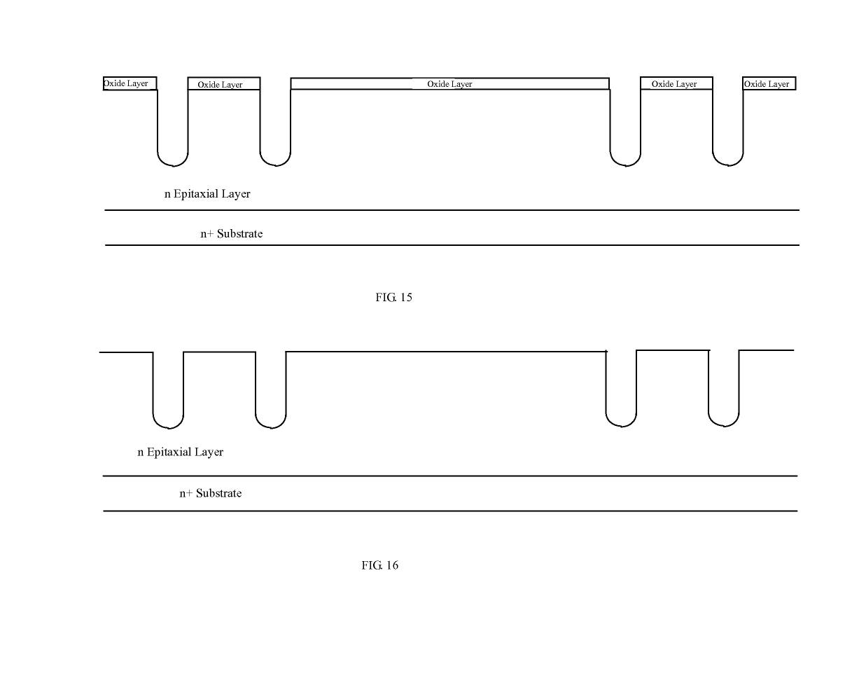

As shown in FIG. 15, gate electrode trenches are formed by etching the exposed epitaxial layer.

As shown in FIG. 16, after the trenches are formed in the epitaxial layer, the oxide layer is removed to expose the entire epitaxial layer.

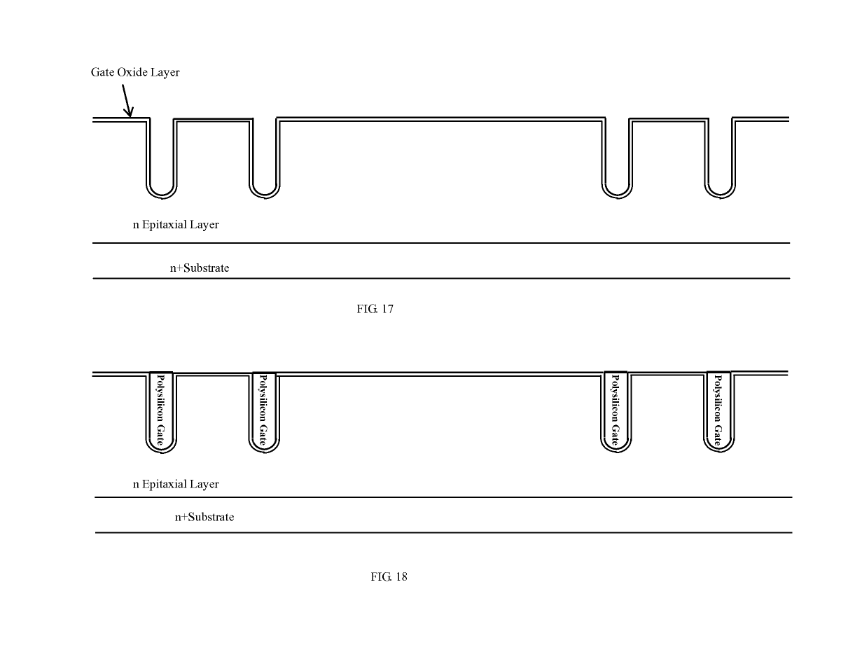

As shown in FIG. 17, the trenches are treated by sacrificing oxidation, and a thin gate oxide layer is formed on the exposed side walls and bottom of the trenches and the upper surface of the epitaxial layer by thermal growth.

As shown in FIG. 18, a layer of polysilicon that contains doping agent is deposited in the trenches, to fill the trenches and cover the top surfaces; then, the polysilicon layer is chemically and mechanically polished.

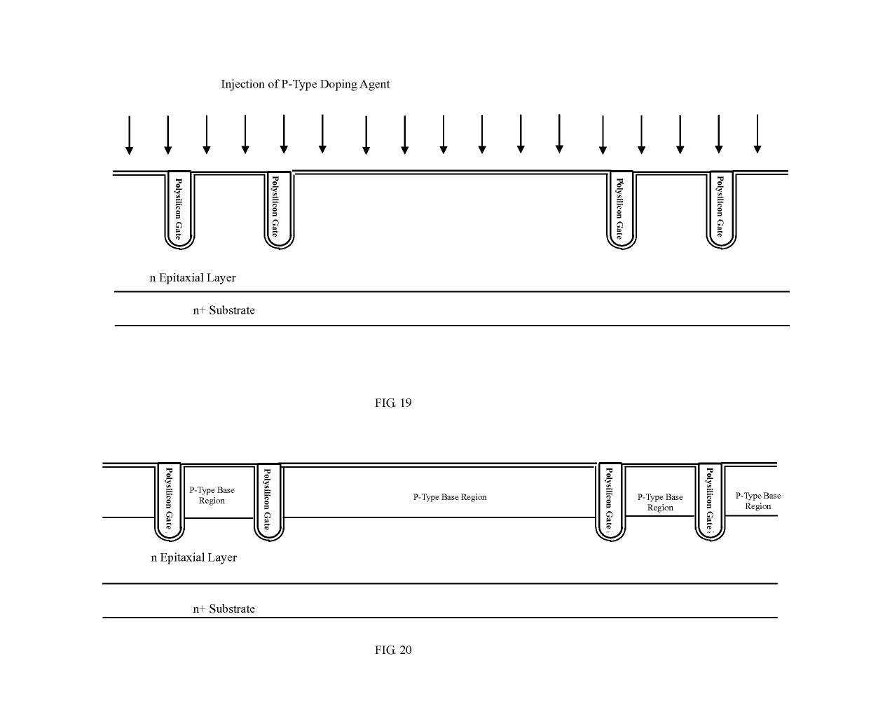

As shown in FIG. 19, the procedures of formation of an oxide layer, exposure of oxide layer through base region mask, and etching of the oxide layer are omitted; instead, a P-type doping agent is injected directly through the gate oxide layer into the epitaxial layer, to form a P-type base region on the epitaxial layer.

As shown in FIG. 20, the P-type base region is diffused into the epitaxial layer by annealing treatment. The depth of the P-type base region depends on several factors, including the type of doping agent, injection energy, concentration, annealing time, etc. The required concentration and depth can be achieved by adjusting these factors.

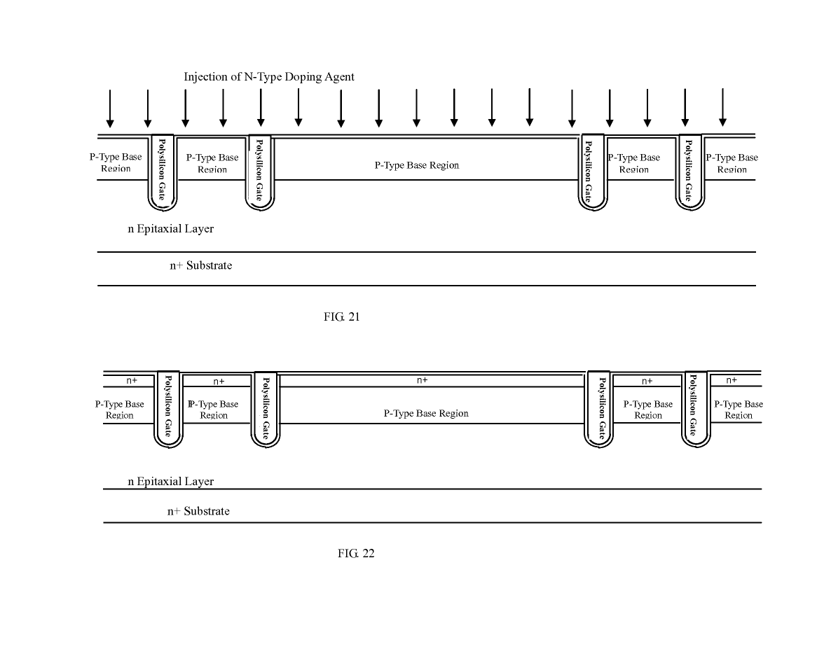

As shown in FIG. 21, the procedures of formation of an oxide layer, exposure of the oxide layer through a source region mask, and etching of the oxide layer are omitted; instead, an N-type doping agent (e.g., phosphorus or arsenic) is injected directly through the gate oxide layer into the P-type base region, to form an N-type source region on the P-type base region.

As shown in FIG. 22, the N-type source region is diffused by annealing treatment, to increase the depth of the N-type source region in the P-type base region. The depth of the N-type source region depends on several factors, including the type of doping agent, injection energy, concentration, annealing time, etc.; the required concentration and depth can be achieved by adjusting these factors.

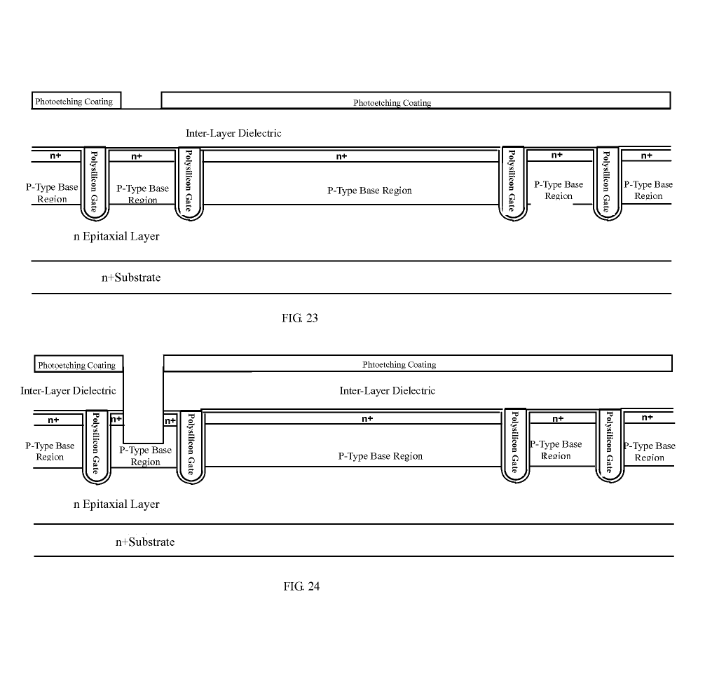

As shown in FIG. 23, to form contact hole trenches in the P-type base region and the N-type source region, B-P glass and silicon dioxide are deposited on the top layer to form an interlayer dielectric.

As shown in FIG. 24, the interlayer dielectric is etched through a contact hole mask to form contact trenches; then, the epitaxial layer that contains the doping agent is etched, so that the contact trenches penetrate more deeply through the source region into the P-type base region.

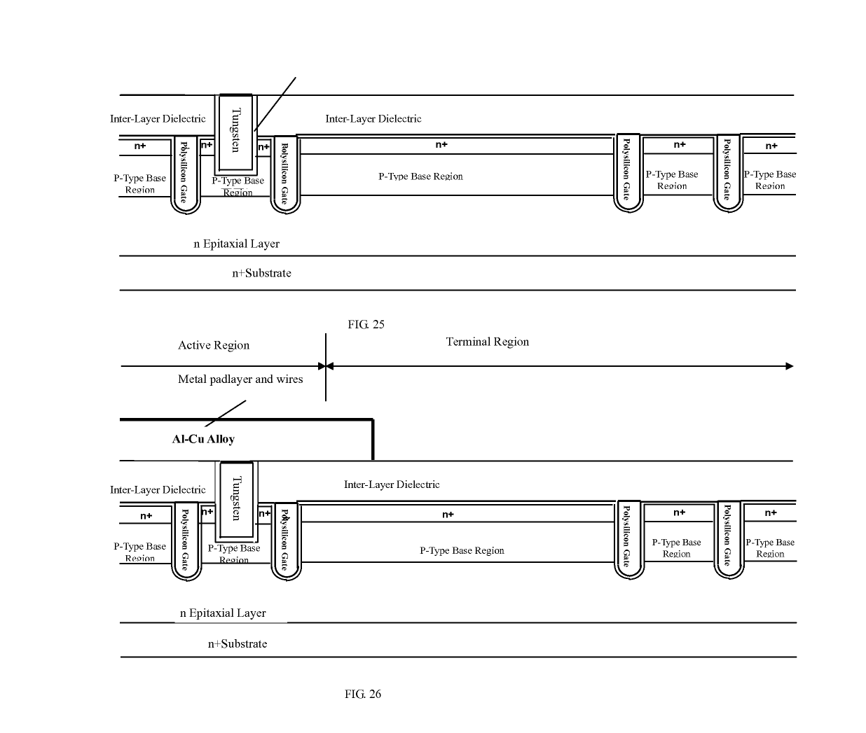

As shown in FIG. 25, the contact trenches are dry-etched, and a titanium/titanium nitride layer is deposited on the side walls and bottom of the trenches and the upper surface of the epitaxial layer; then, the contact trenches are filled with tungsten to form trench plugs, and the top layer of the interlayer dielectric is etched to remove the titanium/titanium nitride and tungsten.

As shown in FIG. 26, a layer of Al—Cu alloy is deposited on the upper surface of the device, and then the metal is etched through a metal mask to form a metal pad layer and wires.

The difference between this embodiment and embodiment 1 is: in embodiment 2, an N-type doping agent is injected after the trenches are etched on the epitaxial layer and the procedure of “injecting a P-type doping agent to form a base region and diffusing the base region into the epitaxial layer by annealing treatment”, while other procedures of embodiment 2 are same as that of embodiment 1.

### Embodiment 3

The manufacturing method in this embodiment is essentially the same as that in embodiment 1, with the main difference lying in the formation of the contact trenches.

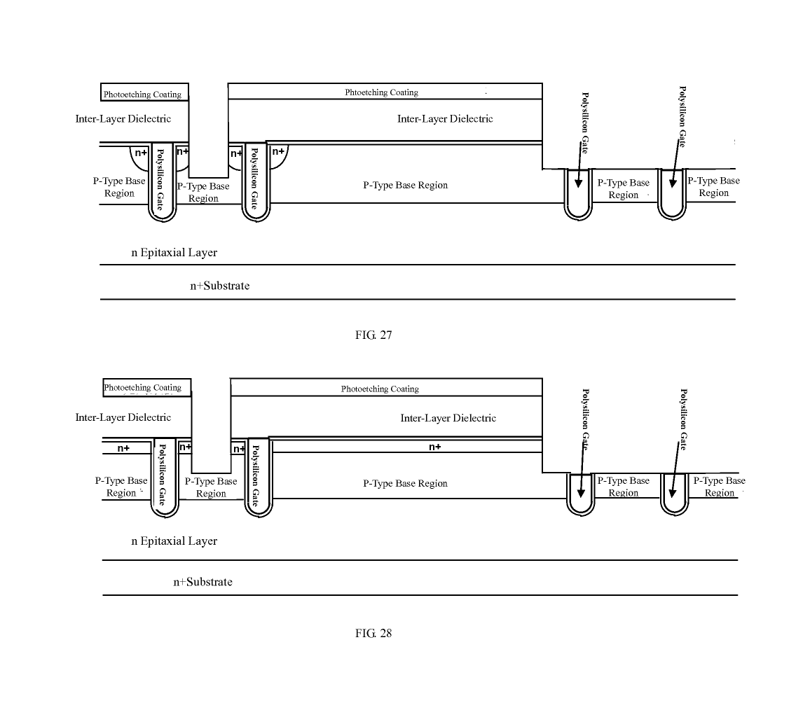

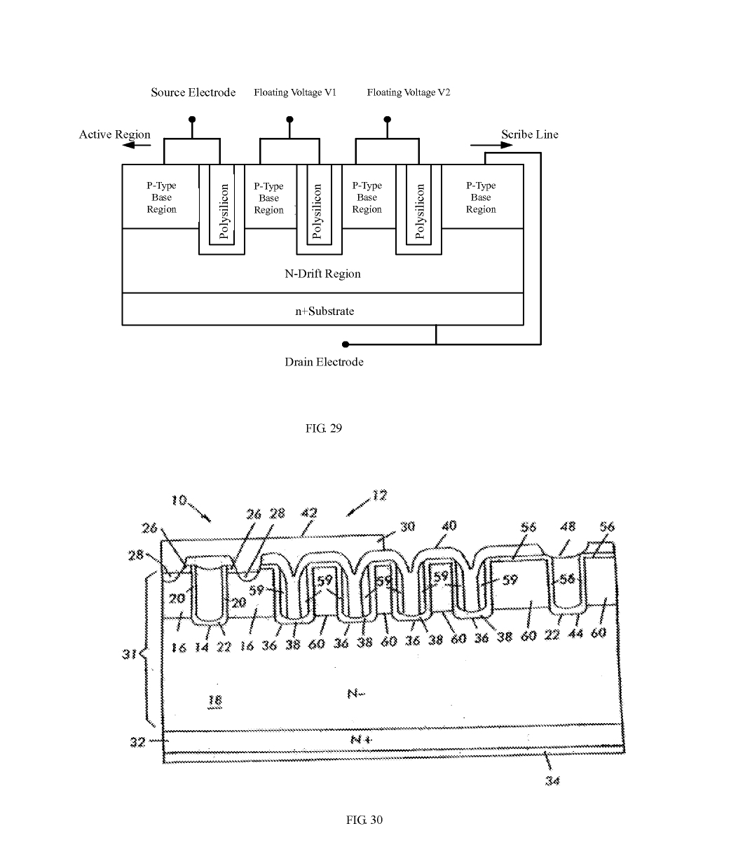

As shown in FIG. 27, the interlayer dielectric is etched through a contact hole mask to form contact trenches; then, the epitaxial layer that contains a doping agent is etched, so that the contact trenches penetrate more deeply through the source region into the P-type base region; during that manufacturing procedure, the N-type source region and partial gate electrode trenches in the terminal region are etched at the same time.

### Embodiment 4

The manufacturing method in this embodiment is essentially the same as that in embodiment 2, with the main difference lying in the formation of the contact trenches.

As shown in FIG. 28, the interlayer dielectric is etched through a contact hole mask to form contact trenches; then, the epitaxial layer that contains a doping agent is etched, so that the contact trenches penetrate more deeply through the source region into the P-type base region; during that manufacturing procedure, the N-type source region and partial gate electrode trenches in the terminal region are etched at the same time.

The person skilled in the art can understand that the above are only some embodiments of the present invention, and are not used to limit the present invention. The present invention non-exclusively relates to the process for manufacturing of semiconductor devices (MOS device, Insulate-Gate Bipolar Transistor device, Bipolar Junction Transistor device, Bipolar diode or Schottky Diode) and corresponding devices. The embodiments of the present invention are described with reference to N-channel trench semiconductor power devices, and also non-exclusively relate to manufacturing of P-channel semiconductor power devices, with the main difference lying in the type of doping agent. While the present invention is described of details in some embodiments, those skilled in the art can make modifications to the technical solution described in the above embodiments, or make equivalent replacements to some technical features of the examples. However, any modification, equivalent replacement, or refinement without departing from the spirit and principle of the present invention shall be deemed as falling into the protection scope of the present invention.

1. A method of manufacturing a trench semiconductor power device, comprising the following steps:
1) etching an epitaxial layer on a substrate through a trench mask to form a plurality of gate electrode trenches, and injecting a doping agent to form a source region and a base region respectively;
2) etching an interlayer dielectric through a contact hole mask to form contact trenches, and filling the contact trenches to form trench plugs; and
3) etching metal through a metal mask to form a metal pad layer and wires.

2. The method of manufacturing a trench semiconductor power device according to claim 1, wherein step 1) further comprises the following steps:
1) dry-etching an exposed oxide layer through the trench mask;
2) injecting an N-type doping agent, and diffusing the N-type doping agent into the epitaxial layer by annealing treatment to form the source region;
3) forming trenches in the epitaxial layer, and removing the oxide layer;
4) treating the trenches by sacrificing treatment, and filling the trenches, to form gate electrode trenches;
5) injecting a P-type doping agent to form a base region, and diffusing the base region into the epitaxial layer by annealing treatment.

3. The method of manufacturing a trench semiconductor power device according to claim 1, wherein step 1) further comprises the following steps:
1) dry-etching an exposed oxide layer through the trench mask;
2) forming trenches in the epitaxial layer, and removing the oxide layer;
3) treating the trenches by sacrificing treatment, and filling the trenches, to form gate electrode trenches;
4) injecting a P-type doping agent to form the base region, and diffusing the P-type base region into the epitaxial layer by annealing treatment;
5) injecting an N-type doping agent into the P-type base region to form the source region, and diffusing the N-type source region into the P-type base region by annealing treatment.

4. The method of manufacturing a trench semiconductor power device according to claim 1, wherein step 2) further comprises the following steps:
1) forming an interlayer dielectric on a top layer, and forming the contact trenches through the contact hole mask;
2) filling the contact trenches to form trench plugs.

5. The method of manufacturing a trench semiconductor power device according to claim 1, wherein step 3) comprises depositing a layer of Al—Cu alloy on the interlayer dielectric, and then etching the metal through the metal mask to form the metal pad layer and wires.

6. The method of manufacturing a trench semiconductor power device according to claim 2, wherein the procedure of treating the trenches by sacrificing treatment and filling the trenches to form gate electrode trenches further comprises the following steps:
1) treating the trenches by sacrificing oxidation;
2) forming a thin gate oxide layer on the exposed side walls and bottom of the trenches and the upper surface of the epitaxial layer by thermal growth; and
3) depositing polysilicon that contains doping agent in the trenches to form a polysilicon layer, filling the trenches and covering a top surface of the trenches, and polishing the polysilicon layer chemically and mechanically.

7. The method of manufacturing a trench semiconductor power device according to claim 2, wherein the injection of N-type doping agent is accomplished by directly injecting an N-type doping agent through the oxide layer into the epitaxial layer, i.e., the procedures of formation of an oxide layer, exposure of the oxide layer through source region mask and etching of the oxide layer before injection of the doping agent through the oxide layer are omitted.

8. The method of manufacturing a trench semiconductor power device according to claim 2, wherein the injection of P-type doping agent is accomplished by directly injecting a P-type doping agent through the thin gate oxide layer into the epitaxial layer, i.e., the procedures of formation of an oxide layer and exposure of the oxide layer through base region mask and etching of the oxide layer before injection of the doping agent through the thin gate oxide layer are omitted.

9. The method of manufacturing a trench semiconductor power device according to claim 3, wherein the injection of N-type doping agent is accomplished by directly injecting an N-type doping agent through the thin gate oxide layer into the P-type base region, i.e., the procedures of formation of an oxide layer and exposure of the oxide layer through source region mask and etching of the oxide layer before injection of the doping agent through the thin gate oxide layer are omitted.

10. The method of manufacturing a trench semiconductor power device according to claim 4, wherein step 1) further comprises the following steps:
1) depositing B-P glass and non-doped silicon dioxide on the top layer to form the interlayer dielectric;
2) etching the interlayer dielectric through contact hole mask, to form contact trenches;
3) etching the N-type source region, so that the contact trenches penetrate through the source region into the base region wherein the source region comprises an N-type source region, and the base region comprises a P-type base region: and
4) Filling the contact trenches to form trench plugs.

11. The method of manufacturing a trench semiconductor power device according to claim 10, wherein, in step 3), the etching of the N-type source region comprises etching the entire N-type source region and partial gate electrode trenches in a terminal region.

12. The method of manufacturing a trench semiconductor power device according to claim 4, wherein step 2) further comprises the following steps: dry-etching the contact trenches and depositing a titanium/titanium nitride layer on side walls and a bottom of the contact trenches, and then filling the contact trenches with tungsten to form the trench plugs, and etching a surface layer of the contact trenches to remove the titanium/titanium nitride and tungsten on a top layer of the interlayer dielectric.

13. A semiconductor power device, manufactured with the manufacturing method as described in claim 1, wherein, the manufacturing method further comprises: depositing a metal layer on a bottom of the substrate.

14. A semiconductor power device, comprising an N-channel trench power MOSFET manufactured with the manufacturing method as described in claim 1.

15. A semiconductor power device, comprising a P-channel trench power MOSFET manufactured with the manufacturing method as described in claim 1.

16. The method of manufacturing a trench semiconductor power device according to claim 3, wherein the procedure of treating the trenches by sacrificing treatment and filling the trenches to form gate electrode trenches further comprises the following steps:
1) treating the trenches by sacrificing oxidation;
2) forming a thin gate oxide layer on the exposed side walls and bottom of the trenches and the upper surface of the epitaxial layer by thermal growth; and
3) depositing polysilicon that contains doping agent in the trenches to form a polysilicon layer, filling the trenches and covering a top surface of the trenches, and polishing the polysilicon layer chemically and mechanically.

17. The method of manufacturing a trench semiconductor power device according to claim 3, wherein the injection of P-type doping agent is accomplished by directly injecting a P-type doping agent through the thin gate oxide layer into the epitaxial layer, i.e., the procedures of formation of an oxide layer and exposure of the oxide layer through base region mask and etching of the oxide layer before injection of the doping agent through the thin gate oxide layer are omitted.
